(19) United States
(12) Patent Application Publication
(10) Pub. No.: US 2007/0096258 A1
(43) Pub. Date: May 3, 2007

(54) Bipolar transistor and method for manufacturing the same

(75) Inventor: Yi-Yeu Lin, Dongshan Township (TW)

Correspondence Address: BIRCH STEWART KOLASCH & BIRCH, PO BOX 747, FALLS CHURCH, VA, 22040-0747, US

(73) Assignee: LITE-ON SEMICONDUCTOR CORP.

(21) Appl. No.: 11/259,091

(22) Filed: Oct. 27, 2005

(51) Int. Cl. H01L 27/082

(52) U.S. Cl. 257/565

(57) ABSTRACT

A bipolar transistor and a method for manufacturing the same are described. A light-doped layer is provided between the base layer and the emitter layer of the bipolar transistor to effectively reduce the invalid current that flows from the base layer back to the emitter layer and increase the required forward bias voltage located between the base layer and the emitter layer to enhance the current gain. The bipolar transistor at least includes a semiconductor substrate, a deep-buried layer formed on the semiconductor substrate, an epitaxy layer formed on the deep-buried layer, a collector layer formed on the epitaxy layer, a base formed on the epitaxy layer, an emitter layer formed within the base layer, and a light-doped layer formed between the base layer and the emitter layer.

### BACKGROUND OF THE INVENTION

1. Field of the Invention

The present invention is related to a bipolar transistor and a method for manufacturing the same, and more particularly to a bipolar transistor and its method that improves the current-driving capability.

2. Description of Related Art

Reference is made to FIG. 1A and FIG. 1B, which is a schematic diagram of a conventional NPN bipolar transistor. The NPN bipolar transistor Q1 serves as a switch because the current that flows between the emitter (E) and collector (C) is controlled by the bias voltage V_{BE} located between the base (B) and the emitter (E). When the base and the emitter of the NPN bipolar transistor are forward biased and V_{BE}>0.7V, the electrons of the emitter (E) can overcome the barrier potential of the N-P conjunction located between the emitter (E) and base (B) and enter the base (B). Then, the electrons pass through the thin base (B) and reach the collector (C). When the bias voltage V_{BE} of the NPN bipolar transistor is 0V, no electrons are emitted from the emitter (E). Hence, no matter what kind of bias voltage is provided between the emitter (E) and the collector (C), no electric current occurs between the emitter (E) and collector (C).

Most people use bipolar transistors to enlarge electronic signals. Under correct operating conditions, the current I_{c} that flows between the emitter (E) and the collector (C) should equal β multiplied by the current I_{b} that flows into the base (B), i.e. I_{c}=β×I_{b}. Hence, β=I_{c}/I_{b}. β is a magnification index that ranges from 30 to 100. In general, the definition of current gain is the ratio of an output current to an input current and the current-driving capability is represented by the magnification index β.

Reference is made to FIG. 2, which is a cross-sectional view of a conventional NPN bipolar transistor. The NPN bipolar transistor 1 has a light-doped P-type substrate 10, a heavy-doped N-type deep-buried layer 20, a light-doped N-type epitaxy layer 30, and a heavy-doped P-type base layer 40 formed on the epitaxy layer 30. The base layer 40 has a base (b) formed thereon.

The NPN bipolar transistor 1 further has a heavy-doped N-type collector 51, which has a collector (C) formed thereon. In addition, the base layer 40 has a heavy-doped N-type emitter layer 50, which has an emitter (E) formed thereon.

Please refer to FIG. 2 again. In the manufacturing process of a conventional NPN bipolar transistor, due to diffusion, the concentration of the surface electric carriers of the base layer 40 are larger than that of the lower layer. Hence, when the conventional NPN bipolar transistor operates normally, the invalid current I_{b1} that flows from the base (B) back to the emitter (E) is large and the driving current I_{b2} is small. The base current I_{b} is the invalid current I_{b1} plus the driving current I_{b2}. Hence, when the invalid current I_{b1} increases, the base current I_{b} also increases. The index β that represents the current driving capability of the bipolar transistor 1 can be expressed as β=I_{c}/I_{b} and I_{b}=I_{b1}+I_{b2}. From these two equations, as I_{b} increases, index β decreases. Hence, in the manufacturing process of the conventional bipolar transistor, the invalid current I_{b1} almost determines the current driving capability of the NPN bipolar transistor. Therefore, how to reduce the invalid current I_{b1} is a crucial issue that needs to be resolved.

### SUMMARY OF THE INVENTION

An objective of the present invention is to provide a bipolar transistor and a method for manufacturing the same. A light-doped layer is provided between the base layer and the emitter layer of the bipolar transistor to increase the required forward bias voltage located between the base layer and the emitter layer to reduce the invalid current that flows from the base layer back to the emitter layer to enhance the current gain.

For achieving the objective above, the present invention provides a bipolar transistor, including at least a semiconductor substrate, a deep-buried layer formed within the semiconductor substrate, an epitaxy layer formed on the deep-buried layer, a collector layer and a base formed on the epitaxy layer, an emitter layer formed within the base layer, and a light-doped layer formed between the base layer and the emitter layer. Therein, the light-doped layer increases a required forward bias between the base layer and the emitter layer and effectively reduces an electric current that flows from the base layer back to the emitter layer to enhance current gain.

For achieving the objective above, the present invention provides a method for manufacturing a bipolar transistor, including providing a semiconductor substrate, forming a deep-buried layer within the semiconductor substrate, growing an epitaxy layer on the semiconductor substrate, forming a base layer and a collector layer on the epitaxy layer, forming an emitter layer within the base layer, and forming a light-doped layer between the base layer and the emitter layer. Therein, the light-doped layer increases a required forward bias between the base layer and the emitter layer and effectively reduces an electric current that flows from the base layer back to the emitter layer to enhance current gain.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1A-B is a schematic diagram of a conventional NPN bipolar transistor;

FIG. 2 is a cross-sectional view of a conventional NPN bipolar transistor;

FIG. 3 is a cross-sectional view of a preferred embodiment of an NPN bipolar transistor in accordance with the present invention; and

FIGS. 4A-E are cross-sectional views that show partially completed bipolar transistors in accordance with the preferred embodiment of the present invention.

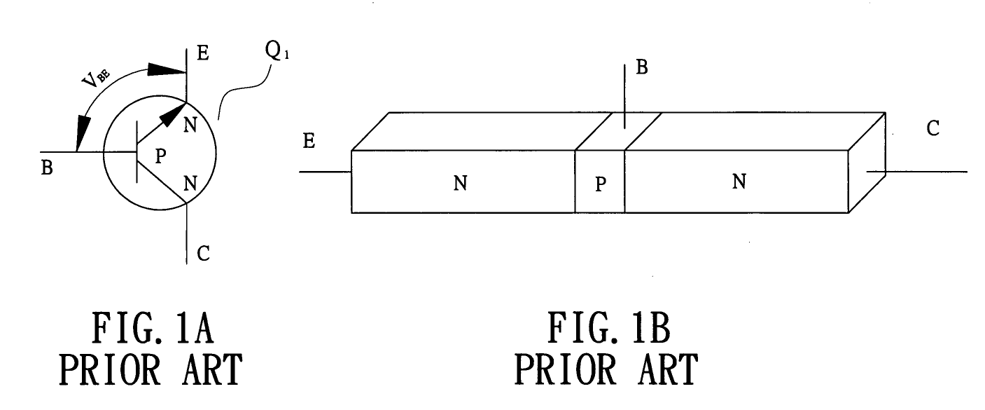

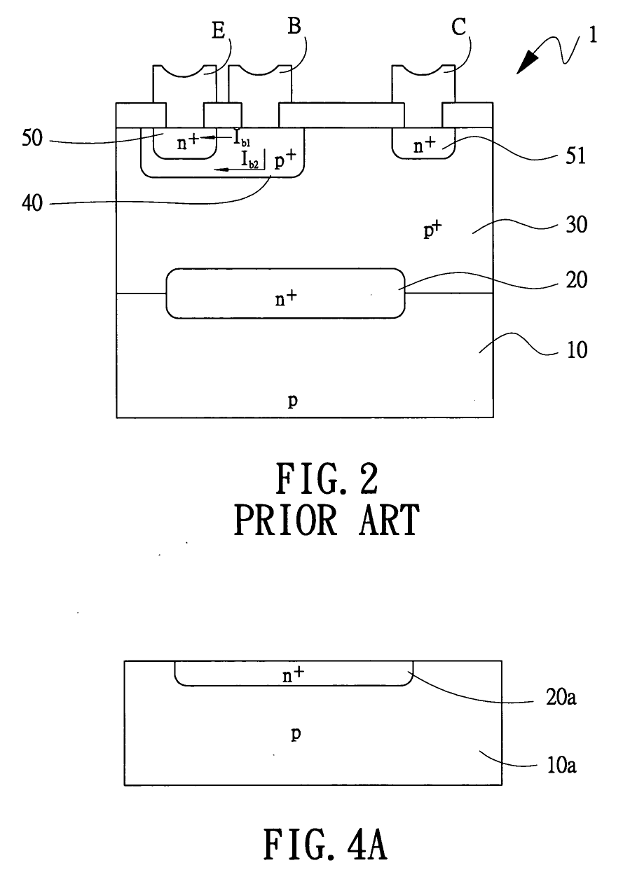

### DETAILED DESCRIPTION OF PREFERRED EMBODIMENTS

The present invention provides a bipolar transistor and a method for manufacturing the same. The bipolar transistor of the present invention can be an NPN or a PNP bipolar transistor. In the following embodiments, only the NPN bipolar transistor is used for explanation and the PNP bipolar transistor is not mentioned because it is only different to the NPN bipolar transistor in doping.

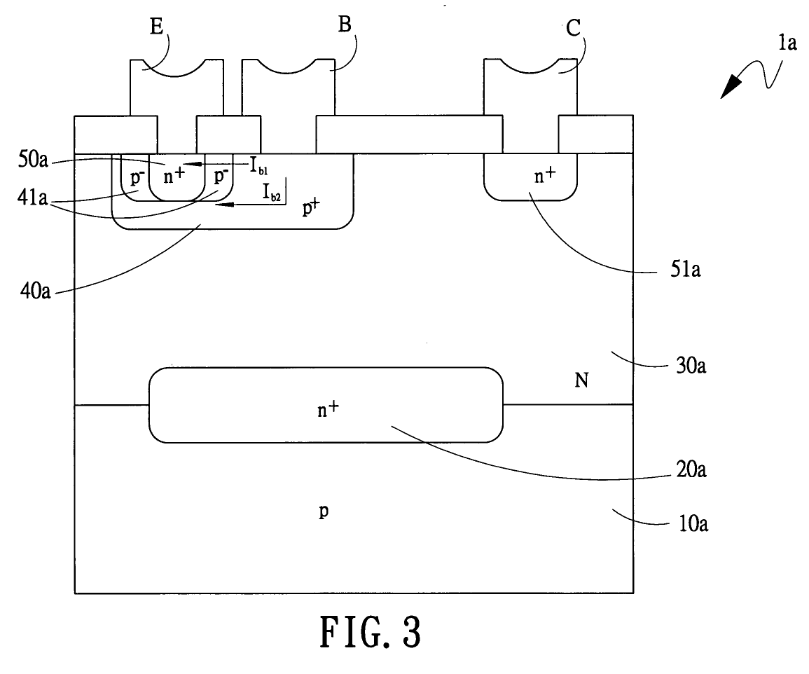

Reference is made to FIG. 3, which is a cross-sectional view of a preferred embodiment of an NPN bipolar transistor in accordance with the present invention. The NPN bipolar transistor 1a has a P-type semiconductor substrate 10a that is doped very lightly. An N-type deep-buried layer 20a is formed on the semiconductor substrate 10a by heavy doping and then an N-type epitaxy layer 30a that is doped very lightly is formed thereon. After that, a P-type base layer 40a and an N-type collector layer 51a are formed on the epitaxy layer 30a by heavy doping. A collector (C) of the NPN bipolar transistor 1a is formed on the collector 51a. A base (B) of the NPN bipolar transistor 1a is formed on the base layer 40a. A heavy-doped N-type emitter layer 50a is formed within the base layer 40a and an emitter (E) of the NPN bipolar transistor 1a is formed on the emitter layer 50a. A light-doped layer 41a is formed between the base layer 40a and the emitter layer 50a. The light-doped layer 40a increases the required forward bias between the base layer 40a and the emitter layer 50a and effectively reduces the electric current I_{b1} that flows from the base layer 40a back to the emitter layer 50a to enhance the current gain.

Please refer to FIG. 3 again. In the present invention, the NPN bipolar transistor 1a uses a light-doped P-type region formed between the base layer 40a and the emitter layer 50a to increase the required transverse forward bias between the base layer 40a and the emitter layer 50a to enhance the current gain when the current that passes thought the NPN bipolar transistor 1a is large.

In the present invention, P-type impurities are doped lightly into the NPN bipolar transistor 1a to form the light-doped layer 41a adjacent to the base layer 40a. In this way, the concentration of the surface carriers of the base layer 40a is reduced. Under normal operation, the electric current I_{b1} that flows from the base (B) of the NPN bipolar transistor 1a back to the emitter (E) is reduced. Thus, the base current I_{b} is reduced. Index β that represents the current-driving capability of the NPN bipolar transistor 1a can be expressed as β=I_{c}/I_{b}. According to this equation, β increases when the base current I_{b} is reduced.

Please refer to FIG. 3 again. The semiconductor substrate 10a is made of light-doped P-type semiconductor. The deep-buried layer 20a is made of heavy-doped N-type semiconductor. The N-type epitaxy layer 30a is made of light-doped N-type semiconductor. The collector layer 51a and the emitter layer 50a are both made of heavy-doped N-type semiconductor. The base layer 40a is made of heavy-doped P-type semiconductor. The light-doped layer 41a is made of light-doped P-type semiconductor.

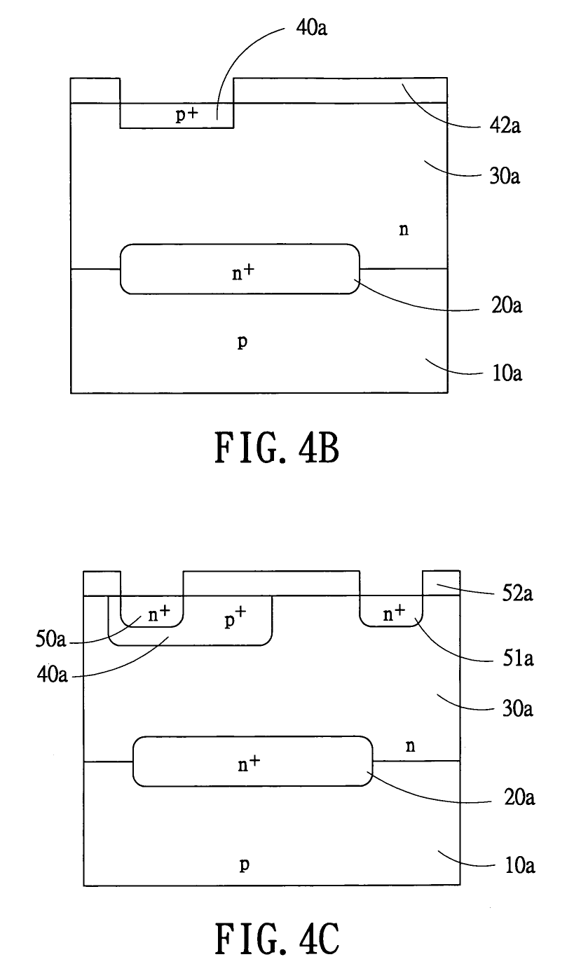

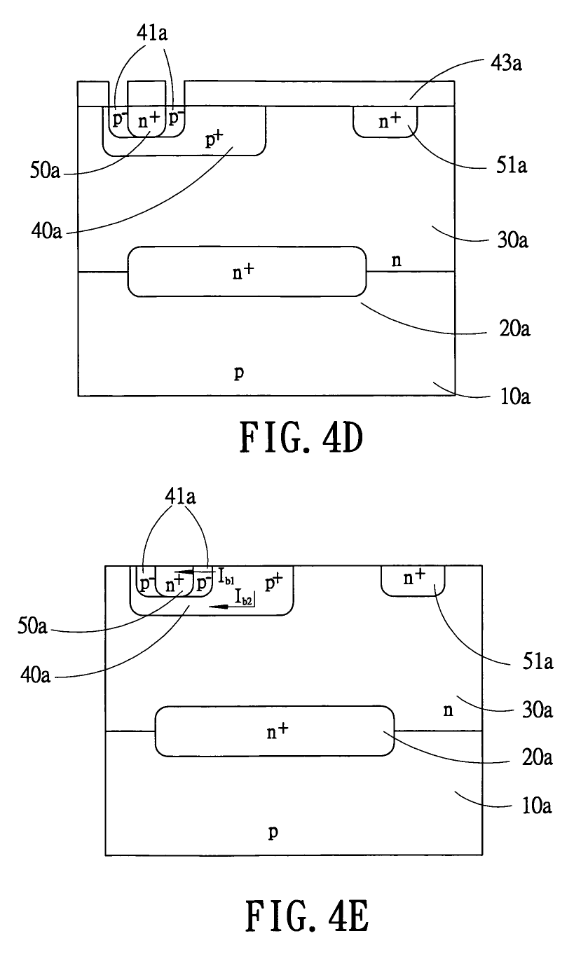

In the following, the method for manufacturing the bipolar transistor of the present invention is described. Reference is made to FIGS. 4A-E, which are cross-sectional views that show partially completed bipolar transistors in accordance with the preferred embodiment of the present invention. Please refer to FIG. 4A. First, the light-doped P-type semiconductor substrate 10a is placed in a wet-oxide environment and oxidized via high temperature circulation. Then, a mask of the deep-buried layer 20a is placed on the oxide layer for making a window and the deep-buried layer 20a is formed by heavy doping through the window.

Please refer to FIG. 4B. A light-doped N-type epitaxy layer 30a is grown on the whole wafer and then a mask 42a is provided thereon. P-type impurities are doped into the epitaxy layer 30a via a window of the mask 42a to form a base layer 40a. The base layer 40a doesn't contact the deep-buried layer 20a. Please refer to FIG. 4C. A mask 52a is then provided on the wafer. N-type impurities are doped though windows of the mask 52a to form two shallow but heavy-doped N-type impurity regions. The N-type impurity region formed within the base layer 40a is the emitter layer 50a and the other is the collector layer 51a.

Please refer to FIG. 4D. A mask 43a is provided on the wafer. N-type impurities are doped via windows of the mask 43a to neutralize the effect of the P-type impurities doped in the base layer 40a to form two shallow P-type light-doped layers 41a. Since the other steps for manufacturing the bipolar transistor of the present invention belong to prior art, they are not described in detail. Please refer to FIG. 4E, which is a cross-sectional view of a completed bipolar transistor of the present invention.

Please refer to FIG. 4E again. The light-doped layer 41a reduces the concentration of a surface electric carrier of the base layer 40a. Under normal operating conditions the NPN bipolar transistor 1a, the electric current I_{b1} that flows from the base layer 40a back to the emitter layer 50a is reduced. Thus, the base current I_{b} is reduced. Index β that represents the current-driving capability of the NPN bipolar transistor 1a can be expressed as β=I_{c}/I_{b}. According to this equation, β increases when base current I_{b} is reduced.

To sum up, the present invention provides a bipolar transistor and a method for manufacturing the same. A light-doped layer 41a is provided between the base layer 40a and the emitter layer 50a of the NPN bipolar transistor. In this way, the electric current that flows from the base layer 40a back to the emitter layer 50a is reduced and the required forward bias between the base layer 40a and the emitter layer 50a is increased. Thereby, the current gain of the NPN bipolar transistor is enhanced. In the conventional NPN bipolar transistor, due to diffusion, the concentration of surface carriers of the base layer is smaller than that of the lower layer. Hence, the conventional NPN bipolar transistor has a larger invalid current and thus its current-driving capability is limited. The present invention effectively resolves this problem.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are embraced within the scope of the invention as defined in the appended claims.

What is claimed is:

1. A bipolar transistor, comprising:
a semiconductor substrate;
an epitaxy layer formed on the semiconductor substrate;
a collector layer formed on the epitaxy layer;
a base layer formed on the epitaxy layer;
an emitter layer formed within the base layer; and
a light-doped layer formed between the base layer and the emitter layer;
wherein the light-doped layer effectively reduces an electric current that flows from the base layer back to the emitter layer to increase a required forward bias between the base layer and the emitter layer to enhance current gain.

2. The bipolar transistor as claimed in claim 1, further comprising a deep-buried layer formed between the semiconductor substrate and the epitaxy layer.

3. The bipolar transistor as claimed in claim 1, wherein the semiconductor substrate is made of light-doped P-type semiconductor or light-doped N-type semiconductor.

4. The bipolar transistor as claimed in claim 2, wherein the deep-buried layer is made of heavy-doped P-type semiconductor or heavy-doped N-type semiconductor.

5. The bipolar transistor as claimed in claim 1, wherein the epitaxy layer is made of light-doped P-type semiconductor or light-doped N-type semiconductor.

6. The bipolar transistor as claimed in claim 1, wherein the collector layer and emitter layer are made of heavy-doped P-type semiconductor or heavy-doped N-type semiconductor.

7. The bipolar transistor as claimed in claim 1, wherein the base layer is made of heavy-doped P-type semiconductor or heavy-doped N-type semiconductor.

8. The bipolar transistor as claimed in claim 1, wherein the light-doped layer is made of light-doped P-type semiconductor or light-doped N-type semiconductor.

9. A bipolar transistor having at least a collector layer, a base layer, and a emitter layer orderly formed on a semiconductor substrate, the bipolar transistor being characterized in that the bipolar transistor further has a light-doped layer formed between the base layer and the emitter layer, wherein the light-doped layer effectively reduces an electric current that flows from the base layer back to the emitter layer to increase a required forward bias between the base layer and the emitter layer to enhance current gain.

10. The bipolar transistor as claimed in claim 9, wherein the collector layer and emitter layer are made of heavy-doped P-type semiconductor or heavy-doped N-type semiconductor.

11. The bipolar transistor as claimed in claim 9, wherein the base layer is made of heavy-doped P-type semiconductor or heavy-doped N-type semiconductor.

12. The bipolar transistor as claimed in claim 9, wherein the light-doped layer is made of light-doped P-type semiconductor or light-doped N-type semiconductor.

13. A method for manufacturing a bipolar transistor, comprising:
providing a semiconductor substrate;
growing an epitaxy layer on the semiconductor substrate;
forming a base layer on the epitaxy layer;
forming a collector layer on the epitaxy layer;
forming an emitter layer within the base layer; and
forming a light-doped layer between the base layer and the emitter layer.

14. The method as claimed in claim 13, further comprising a step after the step of providing the semiconductor substrate is performed:
Forming a deep-buried layer on the semiconductor substrate.

15. The method as claimed in claim 13, wherein the semiconductor substrate is made of light-doped P-type semiconductor or light-doped N-type semiconductor.

16. The method as claimed in claim 14, wherein the deep-buried layer is made of heavy-doped P-type semiconductor or heavy-doped N-type semiconductor.

17. The method as claimed in claim 13, wherein the epitaxy layer is made of light-doped P-type semiconductor or light-doped N-type semiconductor.

18. The method as claimed in claim 13, wherein the base layer is made of light-doped P-type semiconductor or light-doped N-type semiconductor.

19. The method as claimed in claim 13, wherein the collector layer and emitter layer are made of heavy-doped P-type semiconductor or heavy-doped N-type semiconductor.
